(19) United States
(12) Patent Application Publication
(10) Pub. No.: US 2026/0227708 A1
(43) Pub. Date: Aug. 6, 2026

(54) DESIGN BASED REGI CORRECTION (DBRC) - BASED PHOTOMASK MANUFACTURING METHOD FOR CONTROLLING PATTERN POSITION OF WAFER AND MASK

(71) Applicant: Samsung Electronics Co., Ltd., Suwon-si (KR)

(72) Inventors: Hyoyeon Kim, Suwon-si (KR); Youngsu Sung, Suwon-si (KR); Minjeong Kim, Suwon-si (KR); Jeongmin Kim, Suwon-si (KR); Seoeun Seol, Suwon-si (KR)

(21) Appl. No.: 19/438,063

(22) Filed: Dec. 31, 2025

(30) Foreign Application Priority Data
Feb. 3, 2025 (KR) 10-2025-0013276

(51) Int. Cl. G03F 7/00; G03F 1/36; G03F 9/00

(52) U.S. Cl. CPC G03F 7/706831; G03F 1/36; G03F 7/0005; G03F 7/70625; G03F 7/70633; G03F 7/706837; G03F 9/7092

(57) ABSTRACT

In a method of manufacturing a photomask, a target layout is designed, the target layout having a target pattern to be implemented on a photomask. Overlay error data of a wafer is used to generate a registration correction map. The registration correction map is applied to the target layout to generate a correction layout. An exposure process, a development process, and an etching process are performed on a blank mask to form a photomask. The photomask is inspected based on inspection conditions set based on the correction layout.

### CROSS-REFERENCE TO RELATED APPLICATION

This application claims priority under 35 U.S.C. § 119 to Korean Patent Application No. 10-2025-0013276, filed on February 3, 2025 in the Korean Intellectual Property Office (KIPO), the contents of which are herein incorporated by reference in their entirety.

### BACKGROUND

As various bonding schemes are applied at a wafer level, an asymmetrical warpage may occur, which may result in an overlay error. In order to prevent or reduce the warpage, a hardware of a wafer scanner, such as a lens or a stage, can be adjusted. However, since correction in the X direction and correction in the Y direction cannot be performed completely independently, unwanted deformation may occur. Further, in the case of correction using the hardware, deformation in the X direction and deformation in the Y direction may occur asymmetrically to each other (asymmetric mag).

### SUMMARY

Example implementations provide a method of manufacturing a photomask in order to reduce position errors of a photomask and to normally inspect and measure the photomask.

Example implementations provide a method of manufacturing the semiconductor package.

According to example implementations, in a method of manufacturing a photomask, a target layout is designed, the target layout having a target pattern to be implemented on a photomask. Overlay error data of a wafer is reflected to generate a registration correction map. The registration correction map is reflected on the target layout to generate a correction layout. An exposure process, a development process, and an etching process are performed on a blank mask to form a photomask. The photomask is inspected based on inspection conditions set based on the correction layout.

According to example implementations, in a method of manufacturing a photomask, a target layout is designed, the target layout having a target pattern to be implemented on a photomask. A circuit pattern is formed on a wafer based on the target layout. An overlay error is measured from the circuit pattern of the wafer to obtain overlay error data. Modeling is performed based on the overlay error data. The overlay error data of the wafer is reflected to generate a registration correction map. The registration correction map is reflected on the target layout of the photomask to generate a correction layout. An exposure process, a development process, and an etching process are performed on a blank mask to form the photomask. The photomask is measured based on measurement conditions set based on the correction layout.

According to example implementations, in a method of manufacturing a photomask, a target layout is designed, the target layout having a target pattern to be implemented on a photomask. Overlay error data of a wafer is reflected to generate a registration correction map. The registration correction map is reflected on the target layout of the photomask to generate a correction layout. An exposure process, a development process, and an etching process are performed on a blank mask to form a photomask. A measurement recipe including measurement conditions for measuring a critical dimension and a position error of a pattern formed on the photomask is generated based on the correction layout. An inspection recipe including inspection conditions for inspecting the photomask is generated based on the correction layout. A measurement control signal reflecting the measurement recipe is applied to a measuring device to measure the photomask based on the measurement conditions. An inspection control signal reflecting the inspection recipe is inputted to an inspection device to inspect the photomask based on the inspection conditions.

According to example implementations, a photomask manufacturing device includes an exposure device configured to irradiate an exposure beam onto a substrate to perform an exposure process; a controller configured to apply a control signal to the exposure device to perform the exposure process based on a target layout received from a design system; a corrector connected to the controller and configured to correct a positional error of a pattern implemented on the substrate; and a photomask measuring device configured to measure the pattern formed on the substrate. The controller includes a data corrector configured to design a correction layout by reflecting the positional error on the target layout, and the photomask measuring device includes a measuring device controller configured to measure the substrate based on the correction layout.

In example implementations, the photomask manufacturing device may further include a photomask inspection device configured to inspect the substrate on which the pattern is formed.

In example implementations, the photomask inspection device may include an inspection device controller configured to inspect the substrate based on the correction layout.

In example implementations, the exposure device may irradiate an exposure beam onto the substrate based on the correction layout to perform the exposure.

In example implementations, the corrector may include a wafer measuring device configured to measure an overlay error of a wafer and collect overlay error data, and a registration tool configured to generate a registration correction map based on the overlay error data received from the wafer measuring device.

In example implementations, the exposure device may include a deflector for performing an exposure process based on the registration correction map.

In example implementations, the controller may include a data receiver configured to receive the target layout from the design system and the registration correction map from the registration tool, a data corrector configured to generate a correction layout based on the target layout and the registration correction map received from the data receiver, and an output portion configured to transmit a control signal reflecting at least one of the correction layout and the registration correction map to the exposure device.

In example implementations, the registration tool may generate the registration correction map by modeling the overlay error data.

In example implementations, the data corrector may inversely apply the registration correction map to the correction layout to design a verification layout.

In example implementations, the data corrector may compare the verification layout with the target layout to verify the correction layout.

According to example implementations, in a method of manufacturing a photomask, a target layout having a target pattern to be implemented on a photomask may be designed, overlay error data of a wafer may be reflected to generate a registration correction map. Then, the registration correction map may be reflected on the target layout of the photomask to generate a correction layout, and an exposure process, a development process, and an etching process may be performed on a blank mask to form a photomask. Then, the photomask may be inspected based on the correction layout and the photomask may be measured based on the correction layout.

Performing the exposure process on the blank mask may include reflecting at least one of the registration correction map and the correction layout to perform the exposure process on the blank mask.

Accordingly, an error between a position of an actual pattern implemented on the photomask and a position of the target pattern initially designed may be corrected, so that the photomask in which the actual pattern closer to the layout of the target pattern is implemented may be manufactured. In addition, implementations of the present disclosure can prevent or reduce problems that may occur when adjusting hardware such as a lens or a stage for correction. For example, implementations of the present disclosure may prevent or reduce unwanted deformation and asymmetrical deformation (asymmetric mag), because correction in the X direction and correction in the Y direction cannot be performed completely independently.

In addition, measuring the photomask based on the correction layout may include generating a measurement recipe including measurement conditions for measuring a critical dimension CD and a registration error of a pattern formed on the photomask based on the correction layout, and applying a measurement control signal reflecting the measurement recipe to a measuring device. In addition, inspecting the photomask based on the correction layout may include generating an inspection recipe including inspection conditions for inspecting the photomask based on the correction layout, and applying an inspection control signal reflecting the inspection recipe to an inspection device.

Accordingly, even when the difference between the position of the target pattern of the photomask and the position of the actual pattern implemented on the photomask is greater than an automatic correction range of the inspection device, inspection and measurement of the photomask may be performed normally.

### BRIEF DESCRIPTION OF THE DRAWINGS

Example implementations will be more clearly understood from the following detailed description taken in conjunction with the accompanying drawings. FIGS. 1 to 15 represent non-limiting, example implementations as described herein.

FIG. 1 is a block diagram illustrating a photomask manufacturing device in accordance with example implementations.

FIG. 2 is a view illustrating an exposure device of FIG. 1.

FIG. 3 is a view illustrating a measuring device and an inspection device of FIG. 1.

FIG. 4 is a flow chart illustrating a method of manufacturing a photomask in accordance with example implementations.

FIG. 5 is a view illustrating a target layout of a photomask in accordance with example implementations.

FIG. 6 is a plan view illustrating areas where light is reflected from the photomask and projected onto a wafer in an exposure process using a photomask in accordance with example implementations.

FIG. 7 is a view illustrating points sampled within one shot to measure an actual overlay error of an actual pattern implemented on a wafer.

FIG. 8A is a graph illustrating correction values corresponding to respective measurement coordinates to correct position errors by reflecting measured overlay errors.

FIG. 8B is a graph illustrating a position error correction map generated by performing modeling on the correction values of FIG. 8A in accordance with example implementations.

FIG. 9A is a graph illustrating X direction components of the position error correction map of FIG. 8B.

FIG. 9B is a graph illustrating Y direction components of the position error correction map of FIG. 8B.

FIG. 10 is a plan view illustrating a correction layout obtained by correcting the target layout of FIG. 5 by reflecting the position error correction map of FIG. 8B in accordance with example implementations.

FIG. 11A is a graph illustrating a measured position error of a pattern actually implemented on a photomask based on the target layout of FIG. 5.

FIG. 11B is a graph illustrating a measured position error of a pattern actually implemented on a photomask based on the correction layout of FIG. 10.

FIG. 12A is a graph illustrating inputted correction values to correct position errors.

FIG. 12B is a graph illustrating a movement distance of a stage of a measuring device when measuring the critical dimension of the pattern actually implemented on the photomask based on the target layout of FIG. 5.

FIG. 12C is a graph illustrating a movement distance of the stage of the measuring device when measuring the critical dimension of the pattern actually implemented on the photomask based on the correction layout of FIG. 10.

FIG. 13 is a flow chart illustrating a method of manufacturing a photomask in accordance with example implementations.

FIG. 14 is a block diagram illustrating a photomask manufacturing device in accordance with example implementations.

FIG. 15 is a cross-sectional view illustrating an exposure process performed on a blank mask using an exposure device of FIG. 14.

### DETAILED DESCRIPTION

Hereinafter, example implementations will be explained in detail with reference to the accompanying drawings.

Modeling may be performed to reflect the overlay error to generate a registration correction map, and a deflector of an exposure device may be controlled based on the registration correction map to adjust a position of a pattern formed on a photo mask, thereby alleviating the overlay error. However, if a difference between a position of a target pattern of the photomask and a position of an actual pattern implemented on the photomask is greater than an automatic correction range of an inspection device, a large number of defects may be detected and the inspection device may be stopped or measurement values such as critical dimension CD and registration error may be measured abnormally, making it challenging to inspect and measure the photomask normally.

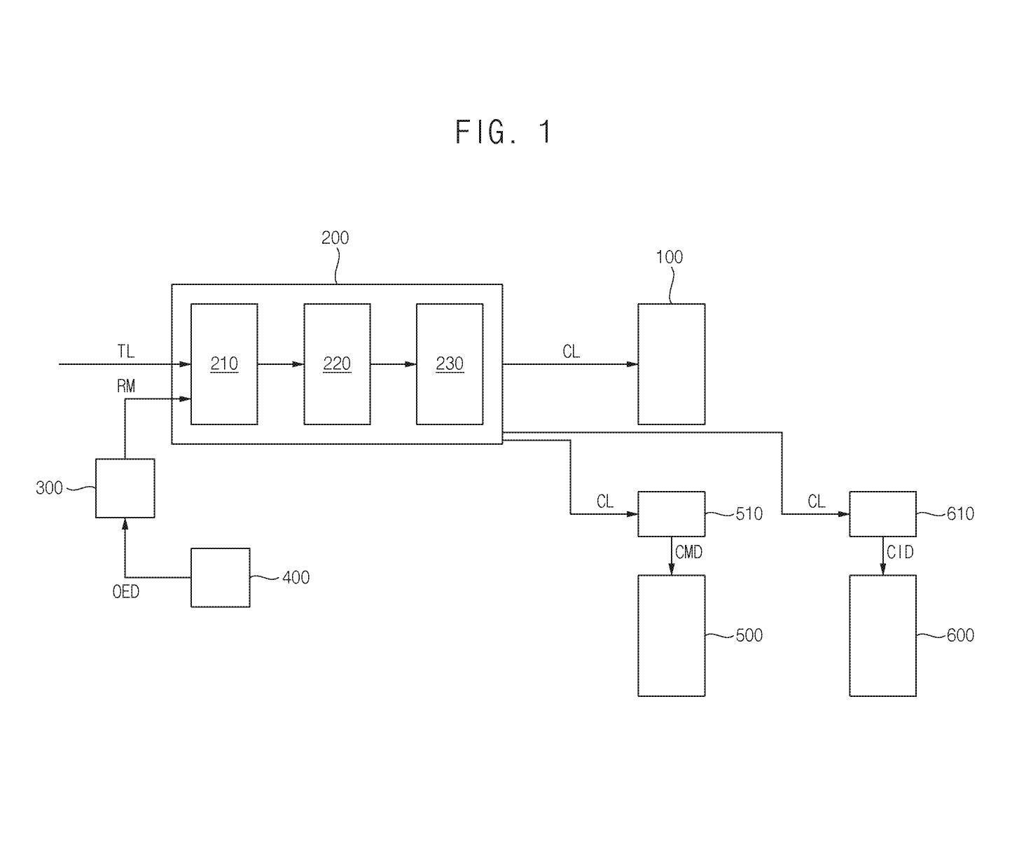

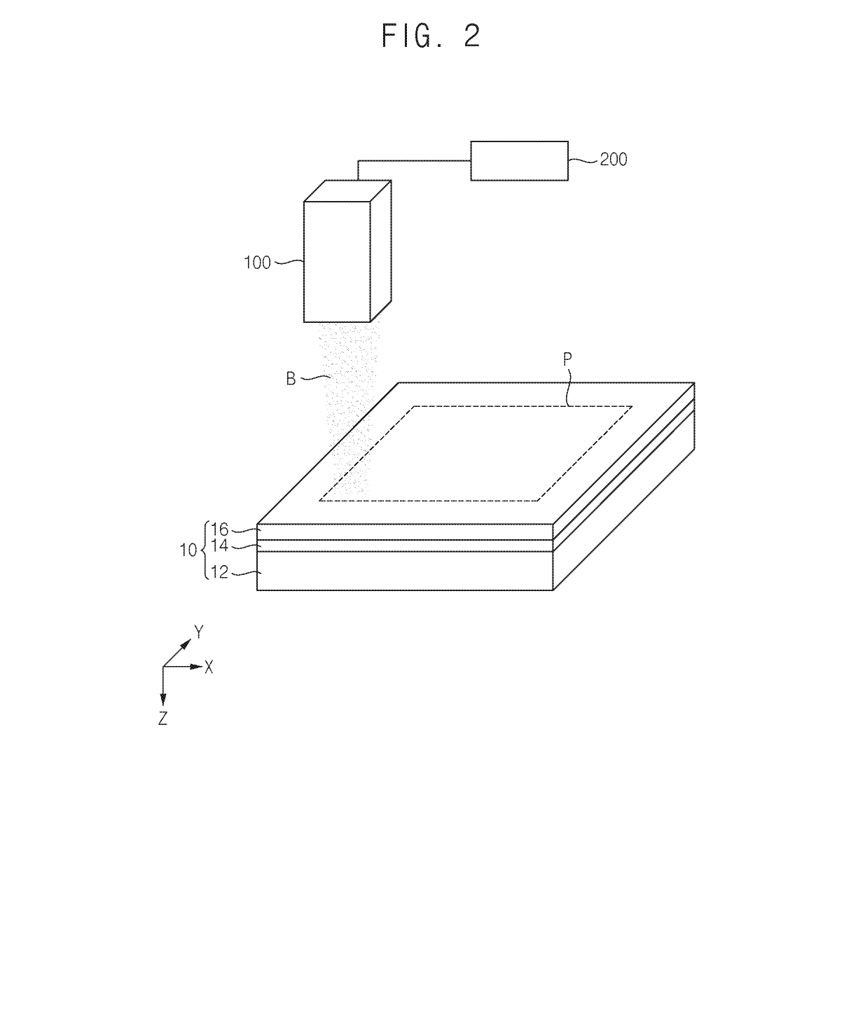

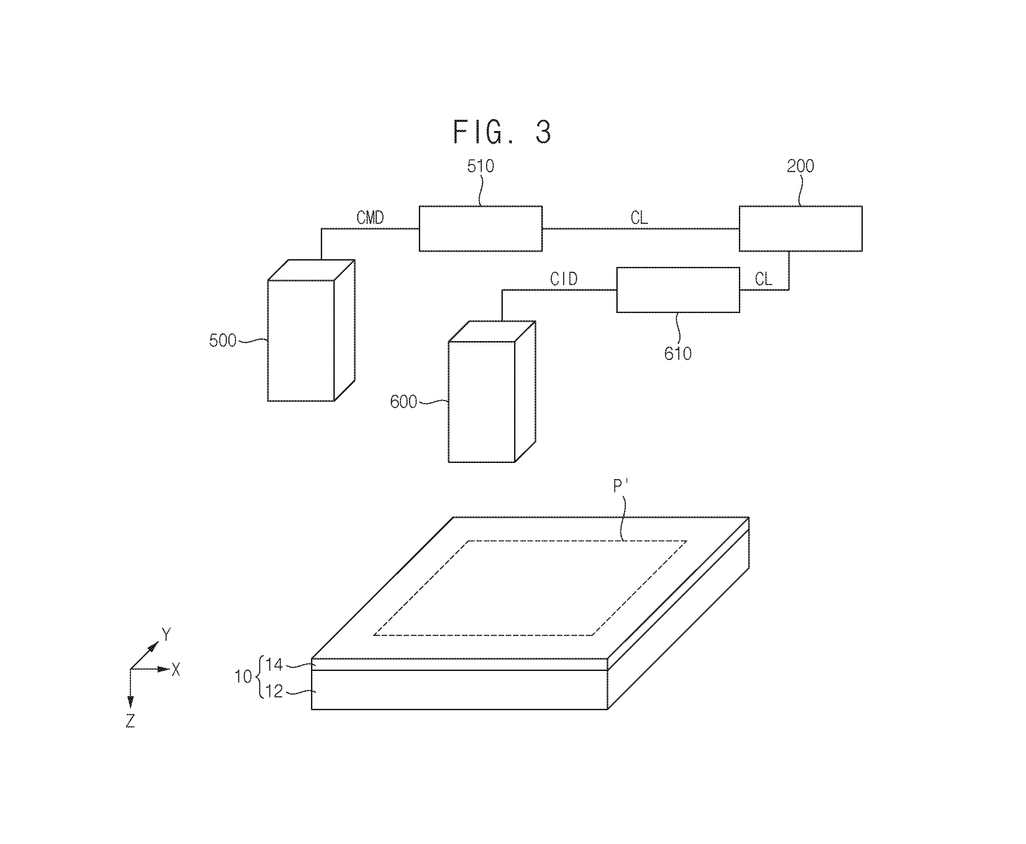

FIG. 1 is a block diagram illustrating a photomask manufacturing device in accordance with example implementations. FIG. 2 is a view illustrating an exposure device of FIG. 1. FIG. 3 is a view illustrating a measuring device and an inspection device of FIG. 1.

Referring to FIGS. 1 to 3, a photomask manufacturing device may include an exposure device 100 and a controller 200 configured to control the exposure device 100. The exposure device 100 may expose a substrate 10 with an exposure beam by a control signal according to design data provided to the controller 200. In addition, the photomask manufacturing device may further include a registration tool 300 connected to the controller 200 and configured to process data related to position errors, and a wafer measuring device 400 connected to the registration tool 300 and configured to measure an overlay error of an actual pattern implemented on a wafer. In addition, the photomask manufacturing device may further include a photomask measuring device 500 connected to the controller 200 and configured to measure an actual pattern implemented on a photomask, and a photomask inspection device 600 connected to the controller 200 and configured to inspect the actual pattern implemented on the photomask.

In example implementations, the exposure device 100 may generate a pattern on a substrate 10 using at least one exposure beam B. The exposure device 100 may be a device for writing a pattern on a substrate to which a photosensitive material is deposited. The exposure device 100 may be used to manufacture a photomask or reticle used for a lithography process of a wafer. For example, the exposure beam B may include a laser beam, an electron beam, etc. The exposure device 100 may include a scanning device that directs and scans the exposure beam B toward the substrate 10 on an exposure stage.

The exposure device may include a deflector used for exposure operations. The deflector may deflect the exposure beam onto the substrate to form patterns. In addition, the exposure stage may support and move the substrate. The exposure stage may move in the X direction or the Y direction by actuators.

The substrate 10 may include a mask substrate 12, a light shielding layer 14, and a photosensitive layer 16 sequentially stacked on one another. The mask substrate 12 may be a transparent substrate, a reflective substrate, or an absorbing substrate. For example, the mask substrate 12 may include glass or quartz. The light shielding layer 14 may include a metal layer such as chromium. The substrate 10 may be used as a photomask or reticle used for a lithography process of a wafer. The exposure device 100 may expose the photosensitive layer 16 on the substrate 10 with exposure beams B according to the design data to form a photosensitive pattern P. For example, the substrate may be a blank mask on which no pattern is formed.

When the substrate 10 is exposed with the exposure beam according to the design data, the photosensitive pattern P may have a position error, i.e., a registration error, with respect to the design data. For example, the exposure device may be a device configured to form the photosensitive pattern P having a shape the same as a mask pattern on the design data at a corresponding same position. However, the pattern of the photomask may have a registration error locally or globally due to the position error of the pattern that occurs during a photomask manufacturing process. For example, the photomask pattern on the substrate 10 may have a positive (+) or negative (-) shifted amount (registration error) in the X direction or the Y direction.

In example implementations, the controller 200 may be a device configured to output a control signal to the exposure device 100 such that the exposure device 100 exposes the substrate with the exposure beam according to the output control signal. The controller 200 may include a data receiver 210, a data corrector 220, and an output portion 230. In addition, the controller 200 may be connected to the registration tool 300 that is connected to the wafer measuring device 400 and may receive data on the position error from the registration tool 300. For example, the controller 200 may output the control signal for controlling the exposure device 100 to expose the exposure beam onto the substrate 10 by reflecting the data on the position error.

The data receiver 210 may receive design pattern data, i.e., target layout TL, from a pattern design system. For example, the design pattern data may be data for the target layout TL having a target pattern to be implemented on a photomask. In addition, the design pattern data may be provided as coordinate values of an outline of the target pattern. The design pattern data may be provided by a combination of polygons (triangles, rectangle, etc.). The design pattern data may be a plurality of sub-patterns having a polygonal shape that constitute one pattern. The design pattern data may include information on sizes and positions of the plurality of sub-patterns.

In addition, the data receiver 210 may receive data on a position error of a pattern actually implemented on a substrate 10. For example, the data receiver 210 may receive the position error data from the registration tool 300.

For example, the wafer measuring device 400 may measure a circuit pattern formed on a wafer by utilizing a photomask on which the target pattern of the target layout is implemented. The wafer measuring device 400 may obtain overlay error data OED from the circuit pattern of the wafer. The overlay error data may be data regarding an error between a position of a circuit pattern formed on an actual wafer and a position of a pattern (target pattern) to be implemented. In this case, the overlay error data may be data regarding sampled portions of the circuit pattern formed on the actual wafer.

In addition, the wafer measuring device 400 may extract components that are difficult to correct with the wafer exposure equipment (or components that cannot be corrected with the wafer exposure equipment) from the overlay error data OED and transmit them to the registration tool 300. For example, the overlay error data OED may include first error data that is easy to correct by adjusting hardware such as a lens or a stage of a scanner of the wafer exposure equipment and second error data that is difficult to correct by adjusting the hardware. The wafer measuring device may extract only the second error data and transmit them to the registration tool 300. For example, the second error data may be error data related to deformation of the pattern in the X direction and deformation of the pattern in the Y direction that occur asymmetrically (asymmetric mag) when adjusting the hardware to correct a position error. In addition, the second error data may be data related to a high order term of the third or higher among multiple terms included in a polynomial obtained by performing a regression analysis (polynomial regression) on the overlay error data OED.

In addition, the registration tool 300 may be connected to the wafer measuring device 400, may receive the overlay error data OED from the wafer measuring device 400, and may generate a registration correction map (position error correction map) RM using the overlay error data OED. For example, the registration correction map may be data that represents correction values on a coordinate plane required to reduce the position error (or eliminate the position error) for each corresponding coordinate. For example, the correction value may be data that represents a horizontal movement distance and direction required for each corresponding coordinate in the form of an arrow on the X-Y plane.

The registration tool 300 may analyze the overlay error data OED and calculate a compensation value to reduce the position error, that is, the error between the position of the circuit pattern formed on the actual wafer and the position of the pattern to be implemented. In addition, the registration tool 300 may perform modeling based on the overlay error data OED to calculate compensation values for unmeasured areas. For example, the modeling may be performed through polynomial interpolation or thin plate spline interpolation.

The data corrector 220 may change position data of the pattern based on the position error correction map RM to correct the design data, that is, the target layout TL.

For example, the position error correction map RM may be reflected in the target layout TL to generate a correction layout CL. The correction layout may be a DBRC (design based registration correction) layout in which the overlay error data OED of the actual circuit pattern implemented on the wafer is reflected in the target layout TL.

In particular, a grid may be defined to divide the target layout TL having the target pattern to be implemented on the photomask into a desired size, and a position error correction map RM may be reflected on the grid to rearrange positions of the sub-patterns included in the target pattern to generate a correction layout CL. The correction layout may be design data in which an X coordinate and a Y coordinate included in the target layout TL are parallel-translated on the X-Y plane in order to reduce the position error (or to remove the position error).

Additionally, the data corrector 220 may perform an interpolation operation on coordinates included in the target layout TL that are not included in the position error correction map RM, and calculate correction values for the coordinates that are not included in the position error correction map RM. For example, the interpolation operation may utilize bilinear interpolation.

In addition, the data corrector 220 may verify the correction layout CL. For example, the data corrector 220 may generate a verification layout by inversely reflecting the position error correction map RM to the correction layout CL. The signs of the correction values included in the position error correction map RM may be reversed, and the coordinates of the correction layout CL may be moved based on the changed correction values. And, the verification layout may be compared with the target layout TL, to confirm whether the correction layout CL is accurately generated. For example, it may be possible to confirm whether the correction layout CL is accurately generated by checking whether there is a pattern that has moved to an incorrect position in the verification layout, whether there is a pattern whose shape has been deformed, whether there is a pattern that has disappeared, etc.

The output portion 230 may output the corrected design data, i.e., the correction layout CL, and output a control signal for controlling the exposure device 100 according to the correction layout CL. The exposure device 100 may expose the substrate 10 with the exposure beam according to the control signal.

In example implementations, the photomask measuring device 500 may be a device that includes a measuring device controller 510 connected to the controller 200 and is configured to measure an actual pattern P’ implemented on a photomask. For example, the photomask measuring device may be a device for measuring a critical dimension CD and a registration error of the actual pattern. For example, the critical dimension may be a minimum size required for the pattern. In addition, the registration error may be a difference between a position of a pattern on design data and a position of an actually implemented pattern.

The measuring device controller 510 may set conditions for measuring the actual pattern P’ based on a correction layout CL transmitted by the controller 200.

For example, the measuring device controller 510 may generate a measurement recipe for measuring the actual pattern P’ based on the correction layout CL and apply a measurement control signal CMD to the photomask measuring device 500 based on the measurement recipe. For example, the measuring device controller may generate a measurement recipe including measurement conditions for measuring the photomask based on the correction layout CL. For example, the measurement recipe may include critical dimension measurement conditions for measuring a critical dimension based on the correction layout CL and position error measurement conditions for measuring a position error based on the correction layout CL. For example, the measurement conditions included in the measurement recipe may include a measurement position, a measurement range, a measurement magnification, an intensity of measurement light, a measurement direction, a measurement mode (setting a measurement method such as reflection or transmission), etc.

For example, the measuring device controller 510 may generate a reference image for measuring at least one of a critical dimension and a position error based on the correction layout CL.

For example, the measuring device controller may output a measurement control signal CMD reflecting the measurement recipe to the measuring device 500 in order to perform measurement according to the measurement recipe.

In example implementations, the photomask inspection device 600 may be a device that includes an inspection device controller 610 connected to the controller 200 and is configured to inspect an actual pattern P’ implemented on a photomask. The photomask inspection device may be a device for inspecting whether the actual pattern contains contaminants, satisfies a critical dimension condition, satisfies a position error condition, etc., to select a defective photomask.

The inspection device controller 610 may generate an inspection recipe for measuring an actual pattern P’ based on the correction layout CL transmitted by the controller 200 and may apply an inspection control signal CID to the photomask inspection device 600 based on the inspection recipe. For example, the inspection device controller may generate an inspection recipe including inspection conditions for inspecting a photomask based on the correction layout CL. Then, the inspection device controller may output an inspection control signal CID reflecting the inspection recipe to the inspection device 600 in order to perform an inspection according to the inspection recipe.

For example, the inspection conditions included in the inspection recipe may include an inspection position, an inspection range, an inspection magnification, an intensity of inspection light, an inspection direction, an inspection mode, etc.

The photomask measuring device 500 and the photomask inspection device 600 may perform automatic correction for a registration error within a certain range. For example, when a first pattern having a first registration error is implemented on a photomask, if a size of the first registration error is within the automatic correction range, measurement and inspection may be performed normally. For example, the automatic correction range may be within ‘0 nm’ to ‘370 nm’. However, this is an example, and it will be understood that this disclosure is not limited thereto. Accordingly, the automatic correction range may be changed depending on the type of the measuring device or the type of the inspection device.

In addition, although not illustrated in the figures, the photomask manufacturing device according to example implementations may further include a heating device for performing a baking process of heating a photoresist layer applied to a photomask, a developing device for performing a developing process of removing a portion of the photoresist layer that has received light (or a portion that has not received light) after an exposure process, an etching device for performing an etching process of removing a portion of a light shielding layer exposed by a photoresist pattern formed by the developing process, and a cleaning device for performing a strip process of removing residues including the photoresist pattern remaining after the etching process.

As mentioned above, the photomask manufacturing device according to example implementations may include the registration tool 300 configured to generate the position error correction map RM based on the overlay error data OED, the controller 200 configured to generate the correction layout CL by reflecting the position error correction map RM to correct the target layout TL, the exposure device 100 configured to perform the exposure process by reflecting the correction layout CL, the photomask measuring device 500 configured to measure a photomask based on the measurement conditions set based on the correction layout CL, and the photomask inspection device 600 configured to inspect the photomask based on the inspection conditions set based on the correction layout CL.

Accordingly, an error between a position of an actual pattern implemented on the photomask and a position of the target pattern initially designed may be corrected, so that the photomask may be manufactured in which the actual pattern is closer to the layout of the target pattern . In addition, problems that may occur when adjusting hardware such as a lens or a stage for correction may be prevented or reduced. For example, unwanted deformation and asymmetrical deformation (asymmetric mag) can be prevented or reduced, because correction in the X direction and correction in the Y direction cannot be performed completely independently.

In addition, even when the difference between the position of the target pattern of the photomask and the position of the actual pattern implemented on the photomask is greater than the automatic correction range of the inspection device, inspection and measurement of the photomask may be performed normally.

Hereinafter, a method of manufacturing a photomask using the photomask manufacturing device of FIG. 1 will be described.

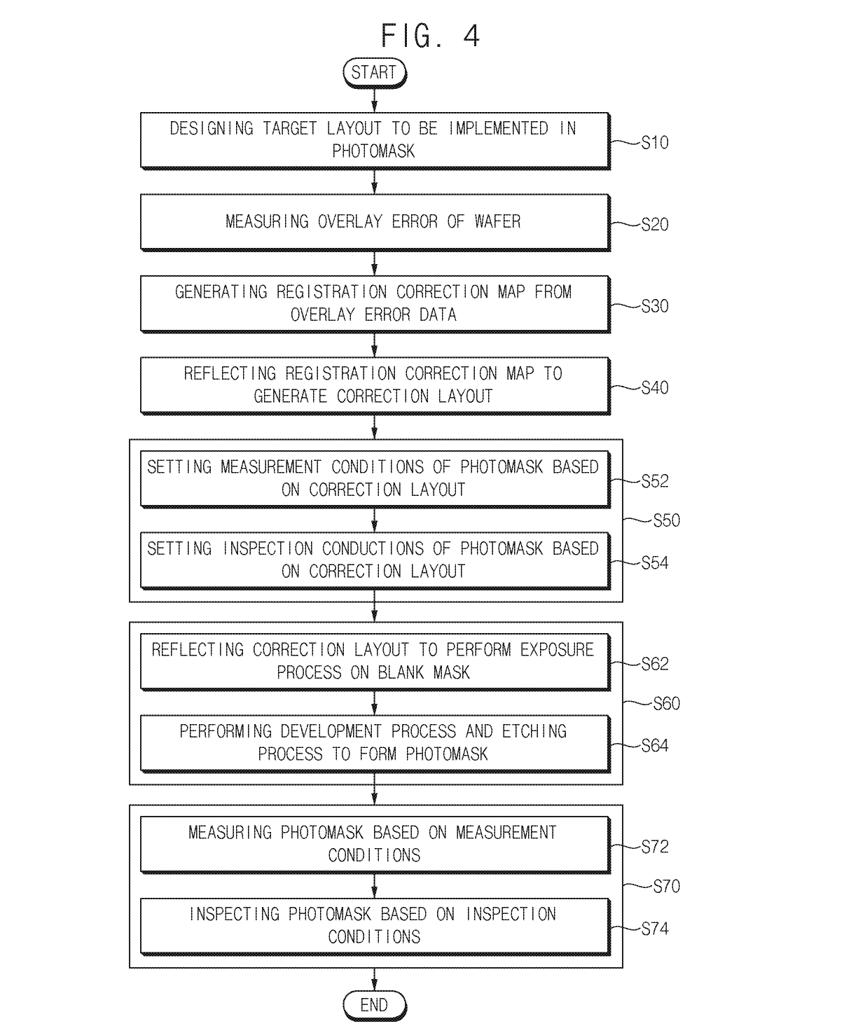

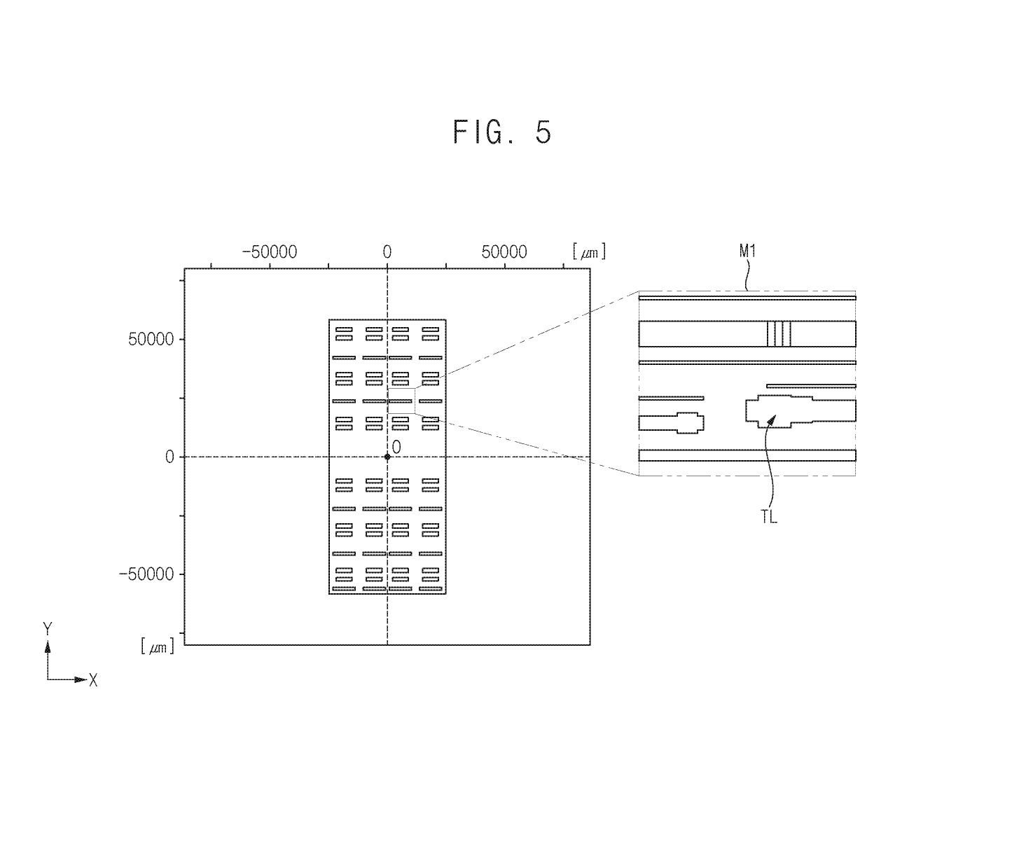

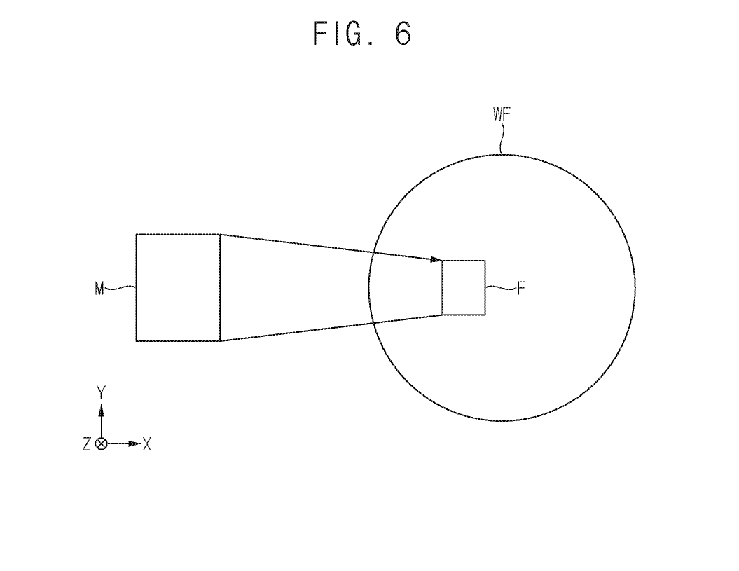

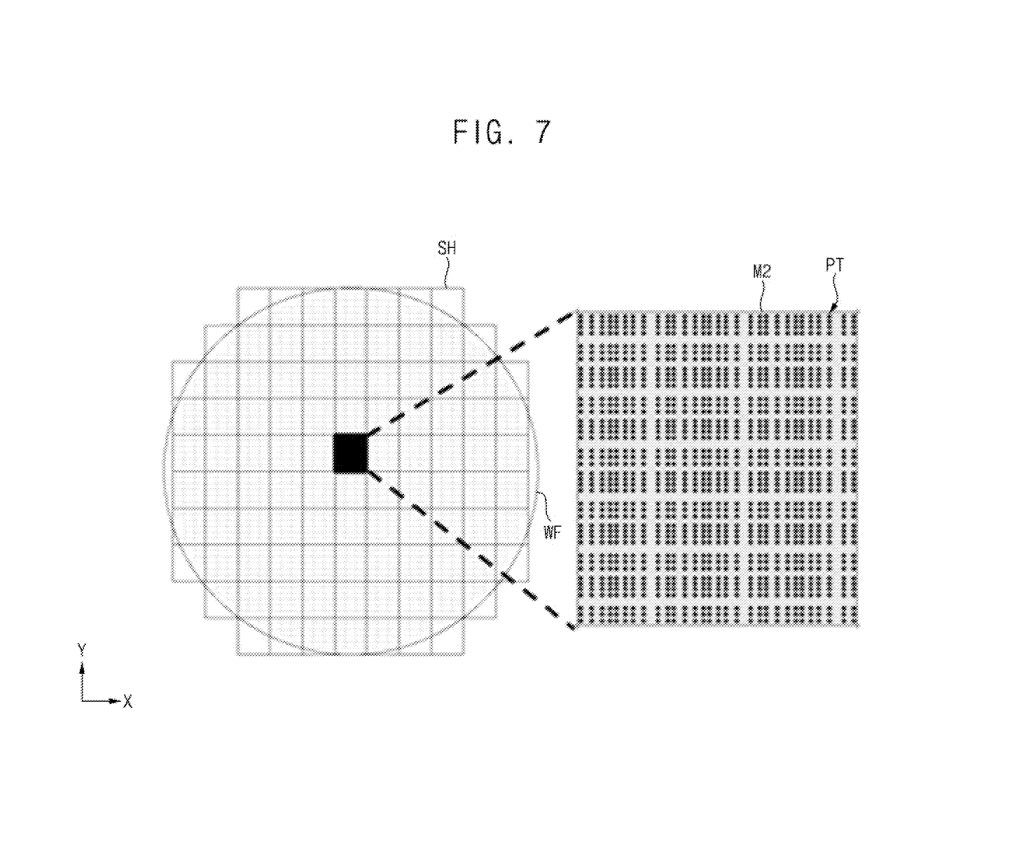

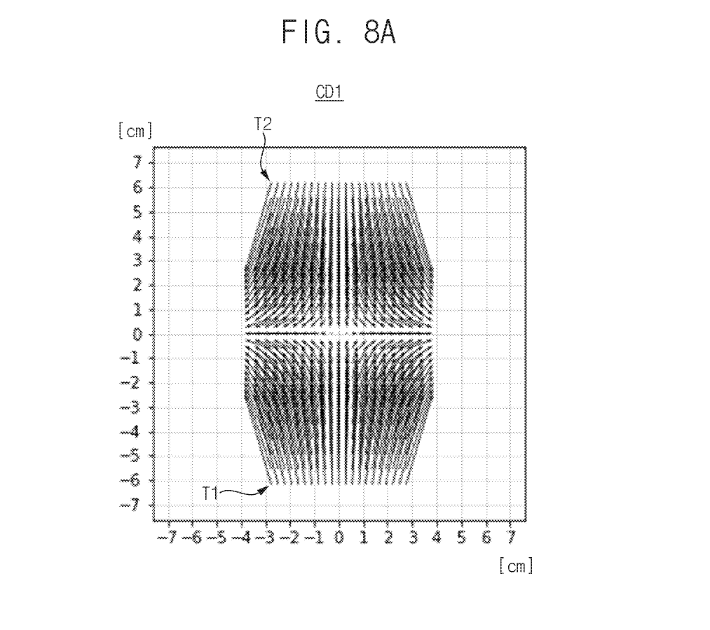

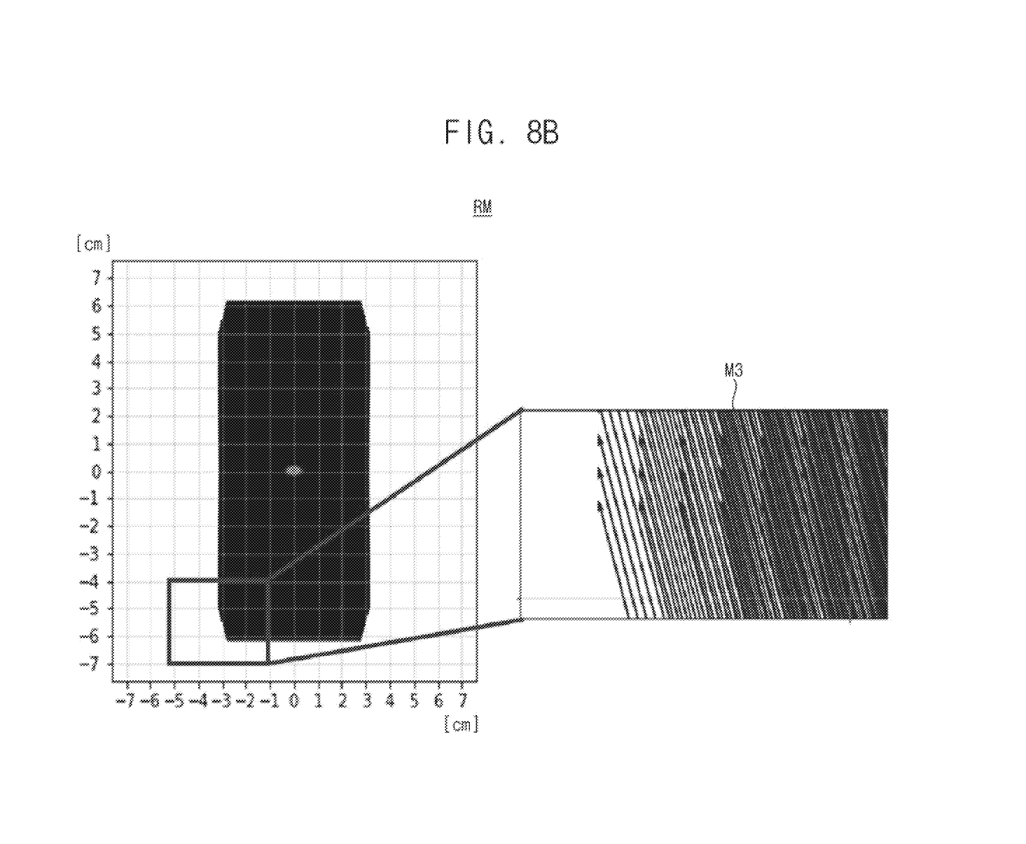

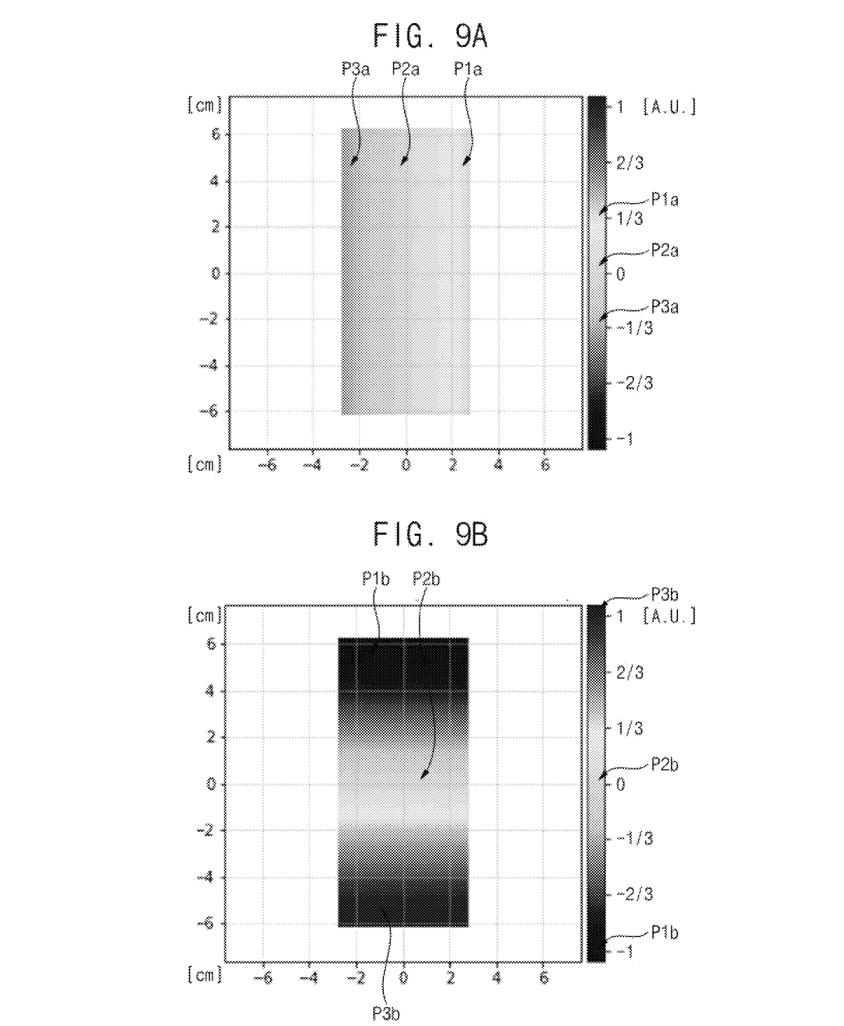

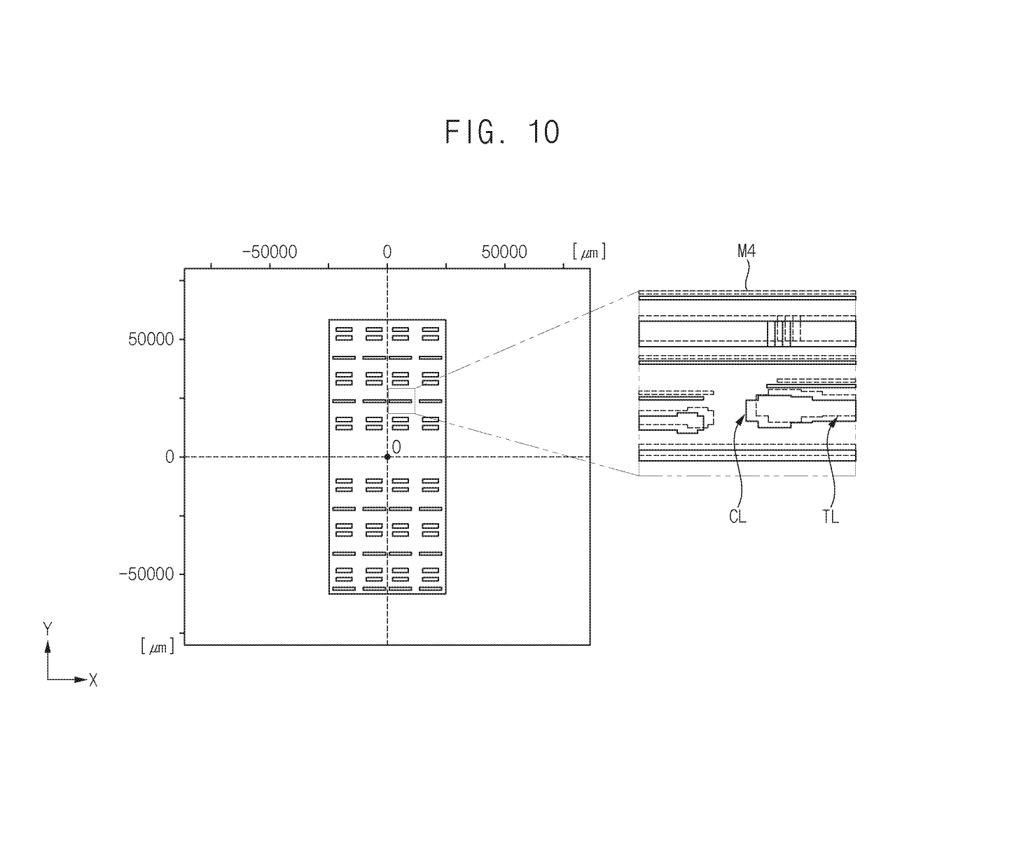

FIG. 4 is a flow chart illustrating a method of manufacturing a photomask in accordance with example implementations. FIG. 5 is a plan view illustrating a target layout of a photomask in accordance with example implementations. FIG. 6 is a plan view illustrating areas where light is reflected from the photomask and projected onto a wafer in an exposure process using a photomask in accordance with example implementations. FIG. 7 is a diagram illustrating points sampled within one shot to measure an actual overlay error of an actual pattern implemented on a wafer. FIG. 8A is a graph illustrating correction values corresponding to respective measurement coordinates to correct position errors by reflecting measured overlay errors. FIG. 8B is a graph illustrating a position error correction map generated by performing modeling on the correction values of FIG. 8A in accordance with example implementations. FIG. 9A is a graph illustrating X direction components of the position error correction map of FIG. 8B. FIG. 9B is a graph illustrating Y direction components of the position error correction map of FIG. 8B. FIG. 10 is a plan view illustrating a correction layout obtained by correcting the target layout of FIG. 5 by reflecting the position error correction map of FIG. 8B in accordance with example implementations.

The photomask manufacturing device used in the photomask manufacturing method described with reference to FIGS. 4 to 7, 8A, 8B, 9A, 9B, and 10 is substantially the same as the photomask manufacturing device described with reference to FIGS. 1 to 3, and thus, same reference numerals will be used to refer to the same or like elements and any further repetitive explanation concerning the above elements will be omitted.

Referring to FIGS. 4 and 5, in a first step S10, a target layout TL having a target pattern may be designed. For example, the target layout may be design data representing a target pattern to be implemented on a photomask. As illustrated in FIG. 5, the target layout may have a target pattern represented in a certain area on the X-Y plane.

Referring to FIGS. 1, 4, 6, and 7, in a second step S20, a photomask M manufactured based on the target layout TL may be projected to form a circuit pattern on a wafer WF, and an overlay error of the circuit pattern may be measured using a wafer measuring device 400, to obtain overlay error data OED.

For example, an exposure process may be performed based on the target layout TL, and then, a development process, an etching process, and a cleaning process may be performed to manufacture the photomask M having the target pattern.

Then, light may be irradiated onto one side of the photomask M, and the light reflected by the photomask M may be directed to the wafer WF by an optical system included in a wafer exposure device and may be incident on one side of the wafer WF.

At this time, an area of the light incident on the wafer WF may be reduced by a certain ratio, that is, a reduction ratio, compared to an area of the light incident on the photomask M. That is, the optical system may have a certain reduction ratio. For example, the optical system may have a reduction ratio of 4:1 for each of the X and Y directions. For example, an area of a wafer WF on which a layout of a pattern included in the photomask M is transferred by a single first exposure process using a photomask M, i.e., one shot, may be defined as a field F. Then, a development process, an etching process, and a cleaning process may be performed on the wafer WF to form a circuit pattern corresponding to the target pattern of the target layout TL.

Then, by measuring the circuit pattern of the wafer WF, data on the overlay error of the wafer WF, that is, overlay error data OED, may be obtained. In particular, the wafer WF may be divided into a virtual area divided into a plurality of shots SH. One of the shots may correspond to the field F where the layout of the pattern included in the photomask M is transferred. Referring to portion ‘M2’ of FIG. 7, a plurality of points PT included in the field F may be sampled to measure the overlay error that occurred in each of the plurality of points PT. For example, the number of the plurality of points may be 1500. The overlay error data OED may include coordinate values of the plurality of points PT on the X-Y plane, a numerical value of the overlay error corresponding to each of the plurality of points PT, etc.

Referring to FIGS. 1, 4, 8A, 8B, 9A and 9B, in a third step S30, a registration correction map RM may be generated based on the overlay error data OED received from the wafer measuring device 400 by utilizing a registration tool 300.

Referring again to FIG. 8A, the overlay error data OED may be analyzed to calculate first correction data CD1 that is able to reduce the overlay error (or remove the overlay error) in the target pattern of the target layout TL. For example, the correction data may include coordinate values of the target layout TL corresponding to the plurality of points PT of the overlay error data OED, correction values required for the respective coordinate values of the target layout TL, etc. For example, it can be seen that a shift is required in the -X (negative X) direction and in the +Y (positive Y) direction for a first coordinate T1, and since the required shift distance is proportional to a size of the arrow, a relatively large shift is required. In addition, it can be seen that a shift is required in the -X (negative X) direction and the -Y (negative Y) direction for a second coordinate T2, and a relatively large shift is required.

Referring again to FIG. 8B, modeling may be performed based on the calculated first correction data CD1 to calculate second correction data CD2 required for points (portions not measured in the above-described overlay error measurement step) that do not correspond to the plurality of points PT of the overlay error data OED, and the first correction data CD1 and the second correction data CD2 may be expressed on X-Y coordinates to generate a position error correction map RM. For example, the modeling may be performed using polynomial interpolation or thin plate spline interpolation.

For example, referring to portion ‘M3’ of FIG. 8B, compared to the first correction data CD1 of FIG. 8A, the position error correction map RM may include correction data for relatively more coordinates.

Referring again to FIG. 9A, an amount of correction required in the X direction may be obtained at each coordinate of the position error correction map RM. For example, it can be seen that a movement of ‘1/3 [A.U]’ in the X direction is required at a first point P1a, ‘~0 [A.U]’ in the X direction is required at a second point P2a, and ‘-1/3 [A.U]’ in the X direction is required at a third point P3a. For example, the amount of correction required in the X direction may be normalized to the range of ‘-1’ to ‘+1’ and displayed in different colors. As used herein, ‘[A.U.]’ represents an arbitrary unit, which can be a dimensionless value derived from normalization or relative measurement. Therefore, the unit does not correspond to a specific physical unit and can be used for comparative analysis.

Referring again to FIG. 9B, an amount of correction required in the Y direction may be obtained at each coordinate of the position error correction map RM. For example, it can be seen that a movement of ‘-1 [A.U.]’ in the Y direction is required at a first point P1b, ‘~0 [A.U.]’ in the Y direction is required at the second point P2b, and ‘+1 [A.U.]’ in the Y direction is required at the third point P3b. For example, the amount of correction required in the Y direction may be normalized to the range of ‘-1’ to ‘+1’ and displayed using different colors. As used herein, ‘[A.U.]’ represents an arbitrary unit, which can be a dimensionless value derived from normalization or relative measurement. Therefore, the unit does not correspond to a specific physical unit and can be used for comparative analysis.

Referring to FIGS. 1, 4, and 10, in a fourth step S40, a controller 200 may generate a correction layout CL by reflecting the position error correction map RM transmitted from the registration tool 300 to the target layout TL transmitted from a pattern design system. For example, the correction layout may be a DBRC (design based registration correction) layout in which the overlay error data OED is reflected to the target layout TL.

For example, a data receiver 210 may receive the position error correction map RM and the target layout TL, and a data corrector 220 may generate a correction layout CL by reflecting the position error correction map RM to the target layout TL.

Referring to portion ‘M4’ of FIG. 10, the correction layout CL and the target layout TL may be confirmed. Each coordinate included in the target layout TL may be rearranged according to the correction value required in the position error correction map RM to generate the correction layout CL. In the figure, the target layout TL (dashed line) is displayed for comparison with the correction layout CL (solid line). However, it can be understood that the target layout TL and the correction layout CL are not included in single design data.

Referring to FIGS. 1 and 4, in a fifth step S50, an output portion 230 may output the correction layout CL generated by the data corrector 220 to a photomask measuring device 500 and a photomask inspection device 600, and measurement conditions of the photomask may set based on the correction layout CL by the photomask measuring device 500 (S52), and inspection conditions of the photomask may set based on the correction layout CL by the photomask inspection device 600 (S54).

For example, a measuring device controller 510 of the photomask measuring device 500 may generate a measurement recipe including the measurement conditions for measuring the pattern of the photomask based on the correction layout CL. For example, the measurement recipe may include critical dimension measurement conditions for measuring a critical dimension based on the correction layout CL and position error measurement conditions for measuring a position error based on the correction layout CL. For example, the measurement conditions included in the measurement recipe may include a measurement position, a measurement range, a measurement magnification, an intensity of measurement light, a measurement direction, a measurement mode (e.g., setting a measurement method such as reflection, transmission, etc.), etc.

For example, a measuring device controller 510 may generate a reference image for measuring at least one of the critical dimensions and the position error based on the correction layout CL. For example, a portion extracted (or cut) from the correction layout CL such as the portion ‘M4’ of FIG. 10 may be generated as the reference image.

In addition, an inspection device controller 610 of the photomask inspection device 600 may generate an inspection recipe including inspection conditions for inspecting the pattern of the photomask based on the correction layout CL. For example, the inspection conditions included in the inspection recipe may include an inspection position, an inspection range, an inspection magnification, an intensity of inspection light, an inspection direction, an inspection mode, etc.

Referring to FIGS. 1, 2 and 4, in a sixth step S60, the output portion 230 may output the correction layout CL generated by the data corrector 220 to an exposure device 100, and an exposure process may be performed on a substrate 10, which is a blank mask, by reflecting the correction layout CL using the exposure device 100 (S62). Accordingly, an exposure process may be performed at positions changed from the original positions of the target pattern. Then, a portion of a photosensitive layer 16 on the substrate 10 may be removed by a development process to generate a photoresist pattern P, and a portion of a light shielding layer 14 on the substrate 10 exposed by the photoresist pattern P may be removed by an etching process to generate a photomask 10 having a pattern P’ within the light shielding layer 14 (S64).

For example, the exposure process may be performed using the exposure device 100 so that a portion corresponding to the correction layout CL on the photosensitive layer 16 on the substrate 10 receives an exposure beam B (or so that a portion corresponding to the correction layout CL does not receive the exposure beam B).

Referring to FIGS. 1, 3 and 4, in a seventh step S70, the photomask measuring device 500 may measure the pattern P’ of the photomask 10 based on the correction layout CL (S72). For example, the measuring device controller 510 may apply a measurement control signal CMD reflecting the previously generated measurement recipe to the measuring device 500, thereby measuring the critical dimension CD and a registration error of the photomask 10 based on the correction layout CL.

Then, the photomask inspection device 600 may inspect the photomask 10 based on the correction layout CL (S74). For example, the inspection device controller 610 may apply an inspection control signal CID reflecting the previously generated inspection recipe to the inspection device 600 to inspect the photomask 10 based on the correction layout CL.

For example, the photomask inspection device may determine a defective photomask by inspecting whether a contaminant exists in the photomask, whether a pattern implemented in the photomask satisfies a critical dimension condition, and whether a pattern implemented in the photomask satisfies a position error condition. In particular, the inspection of the photomask may include a first inspection that acquires an overall image of the SHOT and compares it with a reference image to check whether the size of the pattern and the position error of the pattern satisfy preset criteria, and a second inspection that checks whether the patterns of each of the plurality of die areas provided in the center of the SHOT are identical to each other. In case of the first inspection, if the size of the pattern and the position error of the pattern do not satisfy the preset criteria, the photomask may be determined to be defective. Additionally, in case of the second inspection, if the patterns of each of the multiple die areas are not identical to each other, it may be determined as defective.

For example, inspection (or measurement) of a photomask may be performed using light of different wavelengths. For example, for inspection or measurement of the photomask, light of various wavelengths such as ‘193 nm’, ‘257 nm’, ‘365 nm’, and ‘13.5 nm’ may be used. In addition, argon fluoride ArF may be used as a light source. However, this is only an example, and it will be understood that the present disclosure is not limited thereto. Accordingly, the wavelength, light source, etc. of light used for inspection and measurement of the photomask may be changed.

As mentioned above, in the method of manufacturing a photomask according to example implementations, the target layout TL having the target pattern to be implemented on a photomask may be designed, and a position error correction map RM may be generated by reflecting overlay error data OED of a wafer. Then, the position error correction map RM may be reflected on the target layout TL to generate a correction layout CL, and an exposure process, a development process, and an etching process may be performed on a blank mask 10 to form the photomask. Then, the photomask may be inspected based on the correction layout CL, and the photomask may be measured based on the correction layout CL.

Performing the exposure process on the blank mask 10 may include performing the exposure process by reflecting the correction layout CL.

Accordingly, the error between the position of the actual pattern implemented in the photomask and the position of the target pattern that was originally designed may be corrected, so that a photomask in which an actual pattern closer to the layout of the target pattern is implemented may be manufactured. Further, problems that may occur when performing correction by adjusting hardware such as a lens or a stage may be prevented or reduced. For example, unwanted deformation and asymmetrical deformation (asymmetric mag) can be prevented or reduced because correction in the X direction and correction in the Y direction cannot be performed completely independently.

In addition, measuring the photomask based on the correction layout CL may include setting the critical dimension measurement conditions for measuring critical dimensions CD of patterns formed on the photomask based on the correction layout CL, and setting the position error measurement conditions for measuring position errors of patterns formed on the photomask based on the correction layout CL. In addition, inspecting the photomask based on the correction layout CL may include setting conditions for inspecting the photomask based on the correction layout CL. Accordingly, even when a difference between a position of a target pattern of the photomask and a position of an actual pattern implemented on the photomask is greater than an automatic correction range of the inspection device, inspection and measurement of the photomask may be performed normally.

Hereinafter, it is explained that the critical dimension measurement and position error measurement can be normally performed by utilizing the manufacturing method of the photomask described with reference to FIGS. 4 to 7, 8A, 8B, 9A, 9B, and 10.

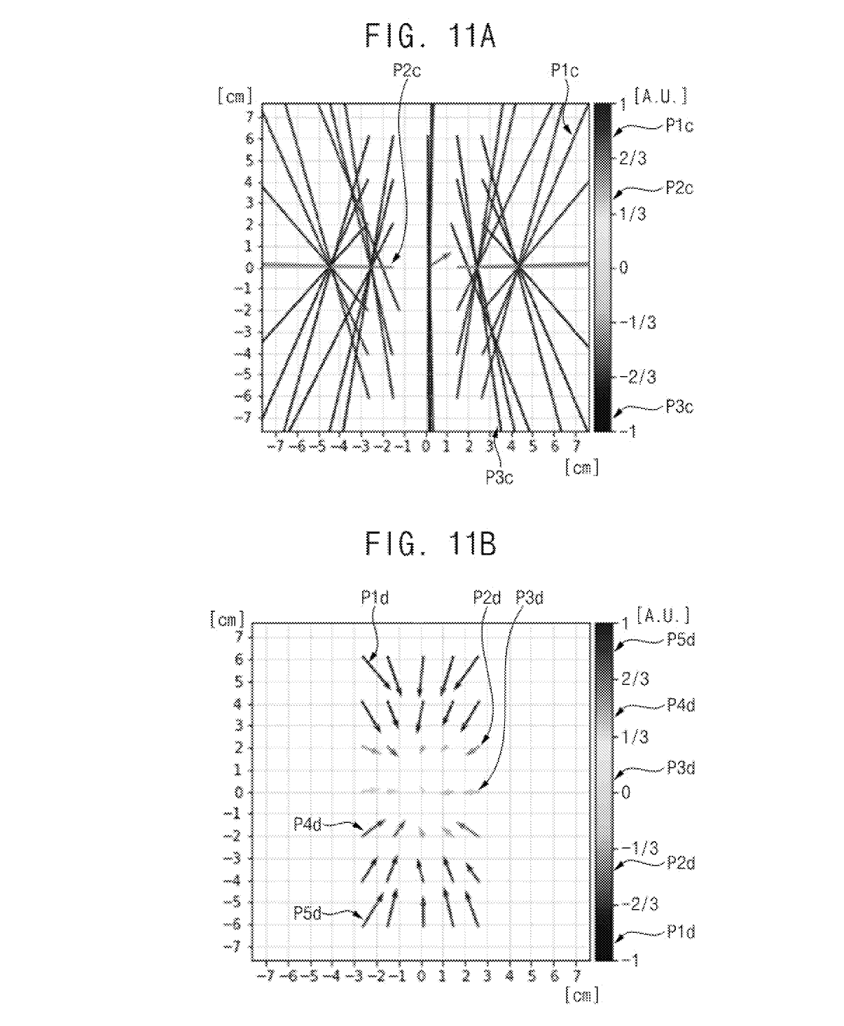

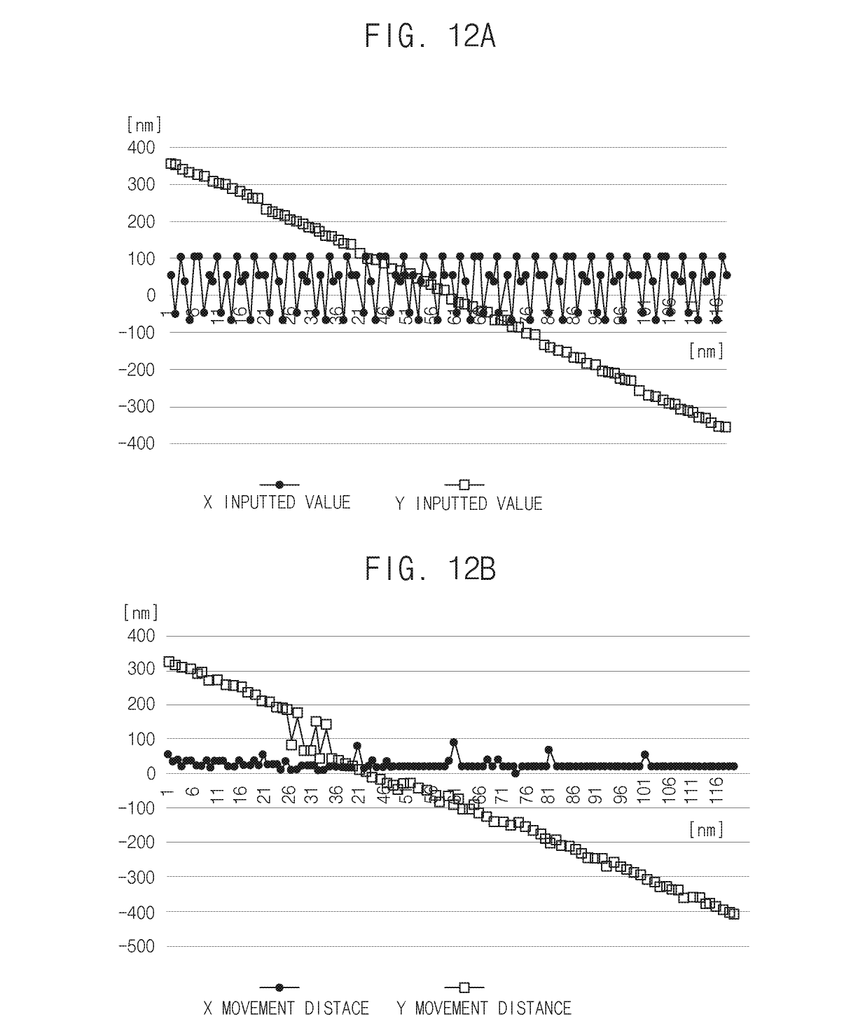

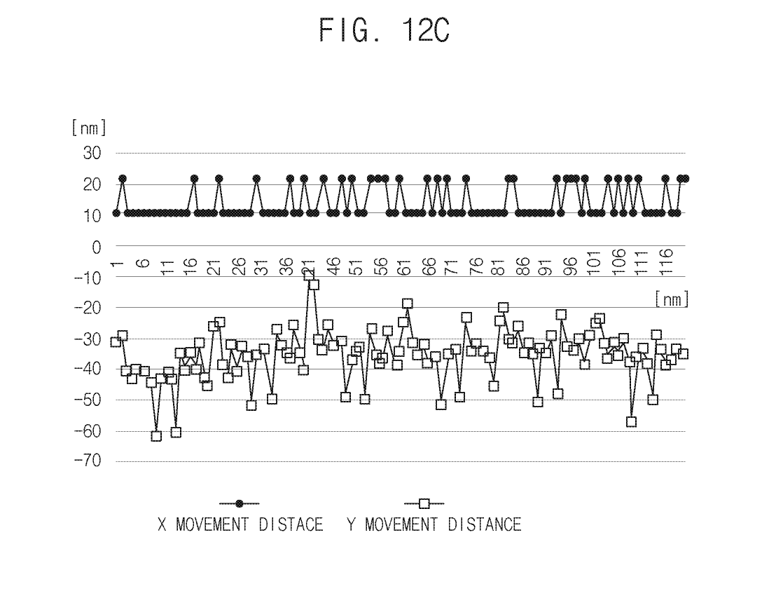

FIG. 11A is a graph illustrating a measured position error of a pattern actually implemented on a photomask based on the target layout of FIG. 5. FIG. 11B is a graph illustrating a measured position error of a pattern actually implemented on a photomask based on the correction layout of FIG. 10. FIG. 12A is a graph illustrating inputted correction values to correct position errors. FIG. 12B is a graph illustrating a movement distance of a stage of a measuring device when measuring the critical dimension of the pattern actually implemented on the photomask based on the target layout of FIG. 5. FIG. 12C is a graph illustrating a movement distance of the stage of the measuring device when measuring the critical dimension of the pattern actually implemented on the photomask based on the correction layout of FIG. 10.

Referring to FIG. 11A, when measuring a position error (registration error) of a pattern actually implemented on a photomask based on the target layout TL of FIG. 5, it can be seen that the registration error is measured abnormally. For example, each of first arrows P1c, P2c, P3c may represent a registration error that occurred at each of measurement coordinates. It can be confirmed that sizes of the first arrows diverge beyond the observation area. For example, the sizes of the first arrows may exceed the automatic correction range of the photomask inspection device 600 (or the photomask measuring device 500). In contrast, referring to FIG. 11B, when measuring the registration error of a pattern actually implemented on a photomask based on the correction layout CL of FIG. 10, it can be seen that the registration error is measured normally. For example, each of second arrows P1d, P2d, P3d may represent a registration error that occurred at each of the measurement coordinates. It can be confirmed that sizes of the second arrows have a normal size within the observation area. For example, the sizes of the second arrows may be within the automatic correction range of the photomask inspection device 600 (or the photomask measuring device 500).

The size of the registration error, as described in FIGS. 11A and 11B, can be normalized to a range of ‘-1’ to ‘+1’ and displayed in different colors. As used herein, ‘[A.U.]’ represents an arbitrary unit, which can be a dimensionless value derived from normalization or relative measurement. Therefore, the unit does not correspond to a specific physical unit and can be used for comparative analysis.

Referring to FIGS. 12A and 12B, when measuring critical dimension CD of the pattern actually implemented on the photomask based on the target layout TL of FIG. 5, it can be seen that the critical dimension is measured abnormally.

In particular, referring again to FIG. 12A, the X input value may be an input value of a movement distance (or correction distance) in the X direction required to correct the registration error. Additionally, the Y input value may be an input value of a movement distance (or correction distance) in the Y direction required to correct the registration error. Referring again to FIG. 12B, the X movement distance may be a distance that a stage of a critical dimension measuring device moves in the X direction to measure the critical dimension CD. Additionally, the Y movement distance may be a distance that the stage of the critical dimension measuring device moves in the Y direction to measure the critical dimension.

Comparing the graphs of the Y input value of FIG. 12A and the Y movement distance of FIG. 12B, it can be confirmed that while the movement distance in the Y direction required to correct the position error is a straight line, the distance that the stage of the critical dimension measuring device actually moves in the Y direction has a break in the middle of the straight line. This difference may occur because, when measuring the critical dimension CD of the pattern actually implemented on the photomask based on the target layout TL, the critical dimension measuring device measures the critical dimension at the wrong location due to a relatively large position error. Therefore, it can be seen that the critical dimension is measured abnormally.

Referring to FIG. 12C, it can be seen that, when measuring the critical dimension CD of the pattern actually implemented on the photomask based on the correction layout CL of FIG. 10, the critical dimension is measured normally. The X movement distance may be the distance that the stage of the critical dimension measuring device moves in the X direction to measure the critical dimension CD. Additionally, the Y movement distance may be the distance that the stage of the critical dimension measuring device moves in the Y direction to measure the critical dimension. For example, the X movement distance may have a size of ‘30 nm’ or less. Additionally, the Y movement distance may have a size of ‘60 nm’ or less.

Accordingly, it can be seen that when measuring the critical dimension CD of the actually implemented pattern on the photomask based on the correction layout CL of FIG. 10, it has a relatively smaller X movement distance and Y movement distance than when measuring the critical dimension CD of the actually implemented pattern on the photomask based on the target layout TL as described in FIG. 12B. The X movement distance and the Y movement distance may be within a normal range that occurs when the critical dimension CD measuring device measures the critical dimension at the correct position.

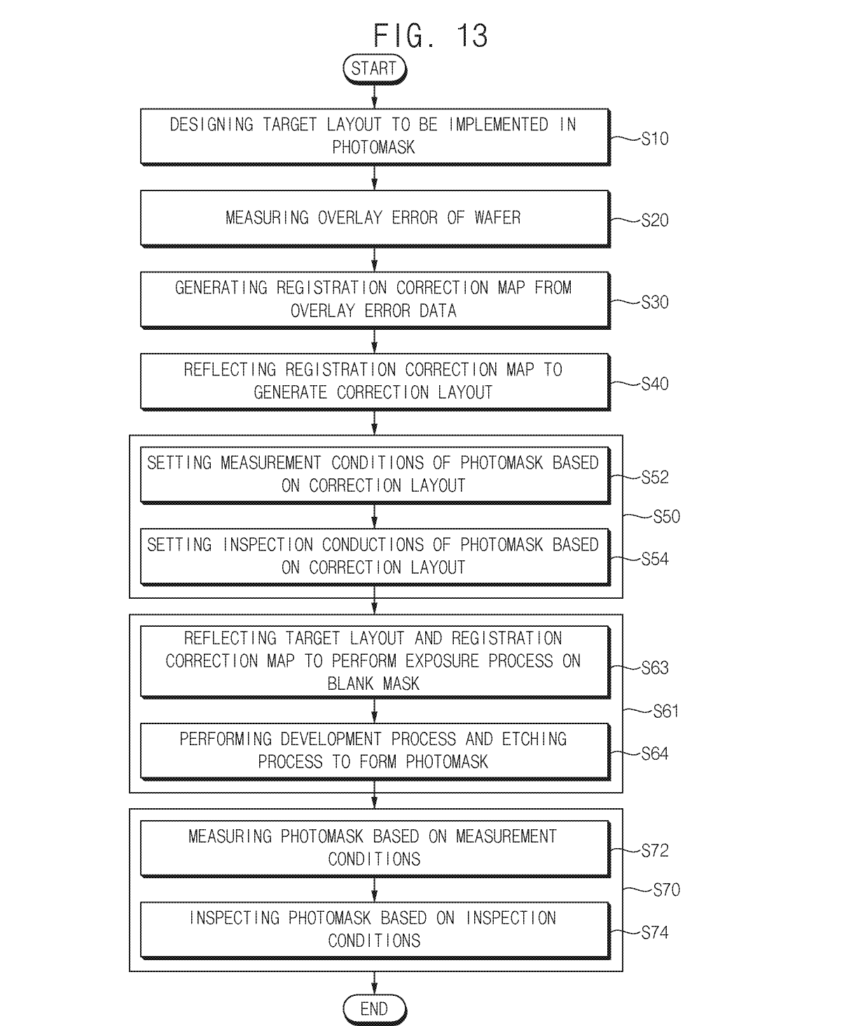

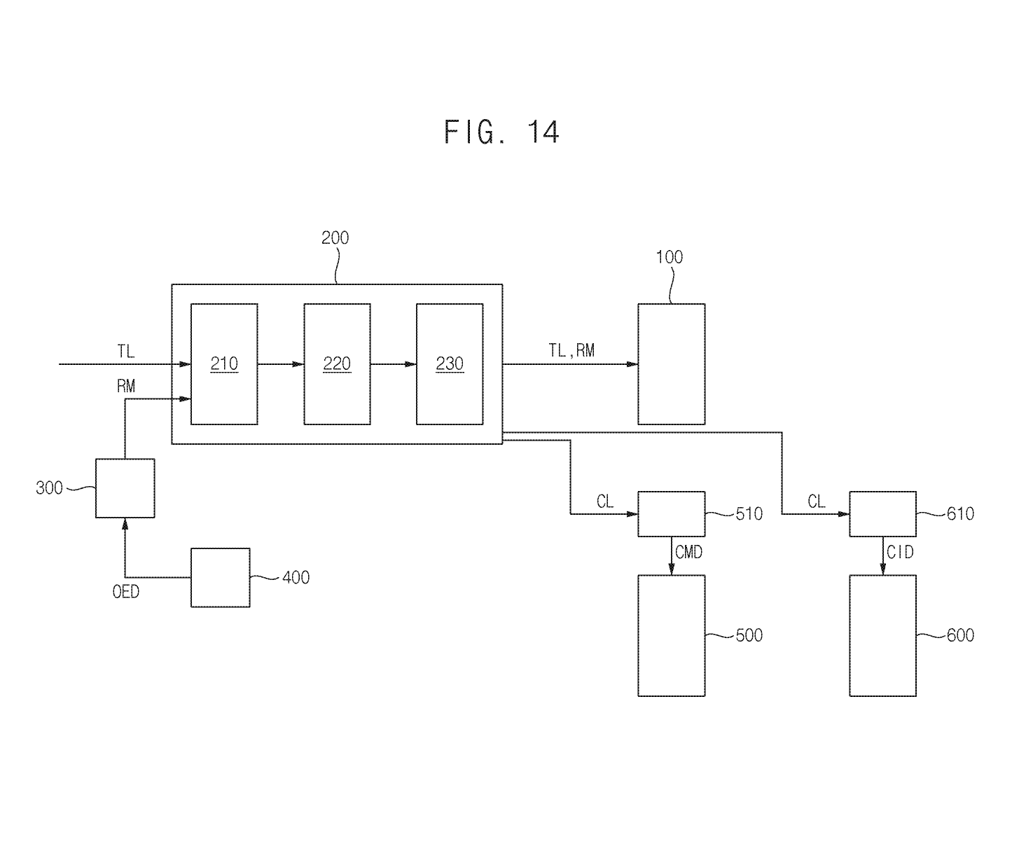

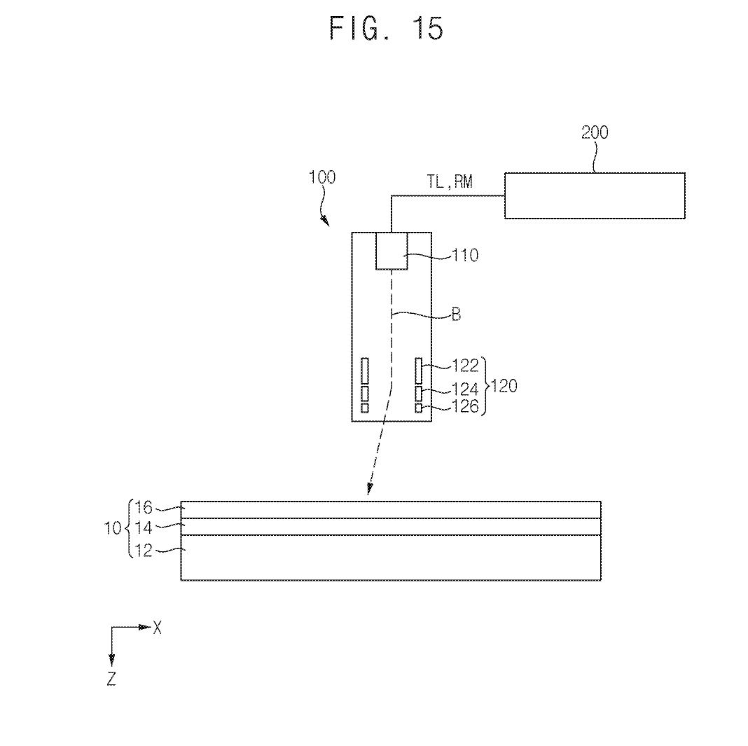

FIG. 13 is a flow chart illustrating a method of manufacturing a photomask in accordance with example implementations. FIG. 14 is a block diagram illustrating a photomask manufacturing device in accordance with example implementations. FIG. 15 is a cross-sectional view illustrating an exposure process performed on a blank mask using an exposure device of FIG. 14.

Since the method includes steps substantially the same as or similar to the method described with reference to FIGS. 4 to 7, 8A, 8B, 9A, 9B, and 10, any further repetitive explanation concerning the above steps will be omitted.

Referring to FIGS. 13 to 15, the first to fourth steps S10 to S40 may be performed to generate a position error correction map RM and a correction layout CL. Then, a fifth step S50 may be performed to generate a measurement recipe including measurement conditions of a photomask based on a correction layout CL, and an inspection recipe including inspection conditions based on the correction layout CL.

Then, in a sixth step S61, an exposure process may be performed on a blank mask 10 by reflecting a target layout TL and the position error correction map CL (S63), and a development process and an etching process may be performed on the blank mask 10 to manufacture a photomask (S64).

For example, the controller 200 may apply a control signal to the exposure device 100 by reflecting the target layout TL received from the design system and the position error correction map RM received from the registration tool 300.

At this time, the exposure device 100 may perform the exposure process by reflecting the position error correction map RM. In particular, referring again to FIG. 15, the exposure device 100 may include an irradiation device 110 configured to irradiate an exposure beam B and a deflector 120 having first to third deflection structures 122, 124, 126 for controlling a direction of the exposure beam B. During the exposure process, the exposure device 100 that irradiates the exposure beam B to a photosensitive layer 16, which is a photoresist layer of the photomask 10, may correct the irradiation direction of the exposure beam, for example, through the deflector 120, based on the position error correction map. That is, by controlling a bias value that the exposure device applies to the deflector according to the value of the position error correction map, the position of an actual pattern implemented on the photomask may be corrected. In example implementations, the exposure beam may be modified in size and direction to offset the pattern position error at each position of the target pattern to perform the exposure process. For example, the exposure beam may be an electron beam (E-beam).

Then, in a seventh step S70, the photomask may be measured and inspected based on the correction layout CL by applying control signals CMD, CID based on the measurement recipe and inspection recipe generated in the fifth step S50.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

The foregoing is illustrative of example implementations and is not to be construed as limiting thereof. Although a few example implementations have been described, those skilled in the art will readily appreciate that many modifications are possible in example implementations without materially departing from the novel teachings and advantages of the present invention. Accordingly, all such modifications are intended to be included within the scope of example implementations as defined in the claims.

What is claimed is:

1. A method of manufacturing a photomask, the method comprising:
generating a target layout having a target pattern to be implemented on a photomask;
generating a registration correction map based on overlay error data of a wafer;
generating a correction layout based on the registration correction map being applied to the target layout;
forming a photomask by performing an exposure process, a development process, and an etching process on a blank mask; and
inspecting the photomask based on inspection conditions that are determined based on the correction layout.

2. The method of claim 1, comprising:
measuring the photomask based on measurement conditions that are determined based on the correction layout.

3. The method of claim 2, wherein measuring the photomask includes:
generating a measurement recipe based on the correction layout, the measurement recipe including measurement conditions for measuring at least one of a critical dimension or a position error of a pattern formed on the photomask; and
applying a measurement control signal to a measuring device, the measurement control signal being based on the measurement recipe.

4. The method of claim 2, wherein measuring the photomask includes extracting a portion of the correction layout to generate a reference image for measuring at least one of a critical dimension or a position error of the photomask.

5. The method of claim 1, wherein inspecting the photomask includes:
generating an inspection recipe including inspection conditions for inspecting the photomask based on the correction layout; and
applying an inspection control signal to an inspection device, the inspection control signal being based on the inspection recipe.

6. The method of claim 1, wherein generating the correction layout includes:
determining a position error of the target layout from the registration correction map;
creating the correction layout by parallel-translating each of first sub-patterns included in the target layout to reduce the position error;
inversely applying the parallel-translation to each of second sub-patterns included in the correction layout to generate a verification layout; and
comparing the target layout with the verification layout to verify the correction layout.

7. The method of claim 1, wherein generating the registration correction map includes:
forming a circuit pattern on the wafer based on the target layout;
measuring an overlay error from the circuit pattern of the wafer to obtain the overlay error data; and
performing modeling based on the overlay error data to extend the overlay error data to include unmeasured areas of the wafer.

8. The method of claim 1, wherein forming the photomask includes:
performing the exposure process on the blank mask based on the registration correction map; and,
performing the development process and the etching process on the blank mask.

9. The method of claim 8, wherein performing the exposure process on the blank mask includes:
providing an exposure device including an irradiation device configured to irradiate an exposure beam and a deflector for controlling an irradiation direction of the exposure beam; and
changing the irradiation direction of the exposure beam through the deflector of the exposure device based on the target layout and the registration correction map.

10. The method of claim 8, wherein generating the registration correction map includes performing the exposure process on the blank mask based on the correction layout.

11. A method of manufacturing a photomask, the method comprising:
generating a target layout having a target pattern to be implemented on a photomask;
forming a circuit pattern on a wafer based on the target layout;
measuring an overlay error from the circuit pattern of the wafer to obtain overlay error data;
performing modeling to extend the overlay error data to include unmeasured areas of the wafer;
generating a registration correction map based on the overlay error data;
generating a correction layout based on the registration correction map being applied to the target layout of the photomask;
forming the photomask by performing an exposure process, a development process, and an etching process on a blank mask; and
measuring the photomask based on measurement conditions that are determined based on the correction layout.

12. The method of claim 11, wherein measuring the photomask includes:
generating a measurement recipe, based on the correction layout, the measurement recipe including measurement conditions for measuring a critical dimension of a pattern formed on the photomask; and
applying a measurement control signal to a measuring device, the measurement control signal based on the measurement recipe.

13. The method of claim 11, wherein measuring the photomask includes:
generating a measurement recipe, based on the correction layout, the measurement recipe including measurement conditions for measuring a position error of a pattern formed on the photomask; and
applying a measurement control signal to a measuring device, the measurement control signal being based on the measurement recipe.

14. The method of claim 11, wherein measuring the photomask includes extracting a portion of the correction layout to generate a reference image for measuring at least one of a critical dimension or a position error of the photomask.

15. The method of claim 11, further comprising:
inspecting the photomask based on inspection conditions that are determined based on the correction layout.

16. The method of claim 11, wherein generating the correction layout includes:
determining a position error of the target layout from the registration correction map;
creating the correction layout by parallel-translating each of first sub-patterns included in the target layout to reduce the position error;
inversely applying the parallel-translation to each of second sub-patterns included in the correction layout to create a verification layout; and
comparing the target layout with the verification layout to verify the correction layout.

17. The method of claim 11, wherein forming the photomask includes:
performing the exposure process on the blank mask based on the registration correction map; and
performing the development process and the etching process on the blank mask.

18. The method of claim 17, wherein performing the exposure process on the blank mask includes:
providing an exposure device including an irradiation device configured to irradiate an exposure beam and a deflector for controlling an irradiation direction of the exposure beam, and,
changing the irradiation direction of the exposure beam through the deflector of the exposure device based on the target layout and the registration correction map.

19. The method of claim 17, wherein generating the registration correction map includes performing the exposure process on the blank mask based on the correction layout.

20. A method of manufacturing a photomask, the method comprising:
generating a target layout having a target pattern to be implemented on a photomask;
generating a registration correction map based on overlay error data of a wafer ;
generating a correction layout based on the registration correction map being applied to the target layout of the photomask ;
forming a photomask by performing an exposure process, a development process, and an etching process on a blank mask;
generating a measurement recipe based on the correction layout, the measurement recipe including measurement conditions for measuring a critical dimension or a position error of a pattern formed on the photomask;
generating an inspection recipe based on the correction layout, the inspection recipe including inspection conditions for inspecting the photomask;
applying a measurement control signal to a measuring device to measure the photomask, the measurement control signal being based on the measurement recipe; and
inputting an inspection control signal to an inspection device to inspect the photomask, the inspection control signal being based on the inspection recipe.
